(19) United States
(12) Patent Application Publication
(10) Pub. No.: US 2020/0381995 A1
(43) Pub. Date: Dec. 3, 2020

(54) VOLTAGE SUPPLY DEVICE AND OPERATION METHOD THEREOF

(71) Applicant: NANYA TECHNOLOGY CORPORATION, New Taipei city (TW)

(72) Inventor: Ting-Shuo HSU, New Taipei City (TW)

(21) Appl. No.: 16/423,146

(22) Filed: May 27, 2019

(51) Int. Cl. H02M 3/07; H03K 3/011; G11C 11/4074; G11C 5/14

(52) U.S. Cl. CPC H02M 3/07; H03K 3/011; H03K 19/20; G11C 5/145; G11C 11/4074

(57) ABSTRACT

The present disclosure is related to a voltage supply device. In accordance with some embodiments of the present disclosure, the voltage supply device comprises a plurality of pump units and a temperature sense circuit. The plurality of pump units are configured to generate a pump voltage in response to an oscillating signal. The temperature sense circuit is configured to sense a system temperature and to generate, according to the system temperature, sense data for generating a control signal configured to enable a first pump array in the plurality of pump units.

### BACKGROUND

Dynamic random access memory (DRAM) is widely used because of its available density, speed, and relatively low cost. In the DRAM circuit, the power system is designed with several charge pumps to provide sufficient operation voltage and current to memory arrays. However, the operation current of the memory arrays varies accordingly with a system temperature of the DRAM circuit during operation. An efficient way to manage power consumption in DRAM circuits at different system temperatures is needed in the application.

### SUMMARY

One aspect of the present disclosure is related to a voltage supply device. In accordance with some embodiments of the present disclosure, the voltage supply device comprises a plurality of pump units and a temperature sense circuit. The plurality of pump units are configured to generate a pump voltage in response to an oscillating signal. The temperature sense circuit is configured to sense a system temperature and to generate, according to the system temperature, sense data for generating a control signal configured to enable a first pump array in the plurality of pump units.

Another aspect of the present disclosure is related to a voltage supply device. In accordance with some embodiments of the present disclosure, the voltage supply device comprises a sense circuit, an oscillator circuit, a pump circuit and a temperature sense circuit. The sense circuit is configured to receive a feedback signal and output a first control signal. The oscillator circuit is coupled to the sense circuit, and configured to receive the first control signal and accordingly output an oscillating signal when the first control signal is enabled. The voltage generating circuit comprises a plurality of first cores and a plurality of second cores. The plurality of first cores are configured to output a voltage in response to the oscillating signal, and the plurality of second cores are configured to be enabled in response to a second control signal to output the voltage. The temperature sense circuit is coupled to the voltage generating circuit, and configured to provide sense data for generating the second control signal according to a system temperature detected by the temperature sense circuit.

Another aspect of the present disclosure is related to a method. In accordance with some embodiments of the present disclosure, the method comprises the following steps: sensing, by a temperature sense circuit, a system temperature, to generate sense data, generating a control signal corresponding to the sense data and controlling, by the control signal, a number of pump units in a pump circuit that is configured to generate a pump voltage, to be enabled.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a voltage supply device, in accordance with some embodiments of the present disclosure.

FIG. 2A and FIG. 2B are schematic diagrams illustrating a control circuit and a plurality of pump units, in accordance with some embodiments of the present disclosure.

FIG. 3 is a flow chart of a method illustrating operations of the voltage supply device in FIG. 1, in accordance with some embodiments of the present disclosure.

FIG. 4 is a schematic diagram of a voltage supply device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the some embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to some embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

The terms “comprise,” “comprising,” “include,” “including,” “has,” “having,” etc. used in this specification are open-ended and mean “comprises but not limited.”

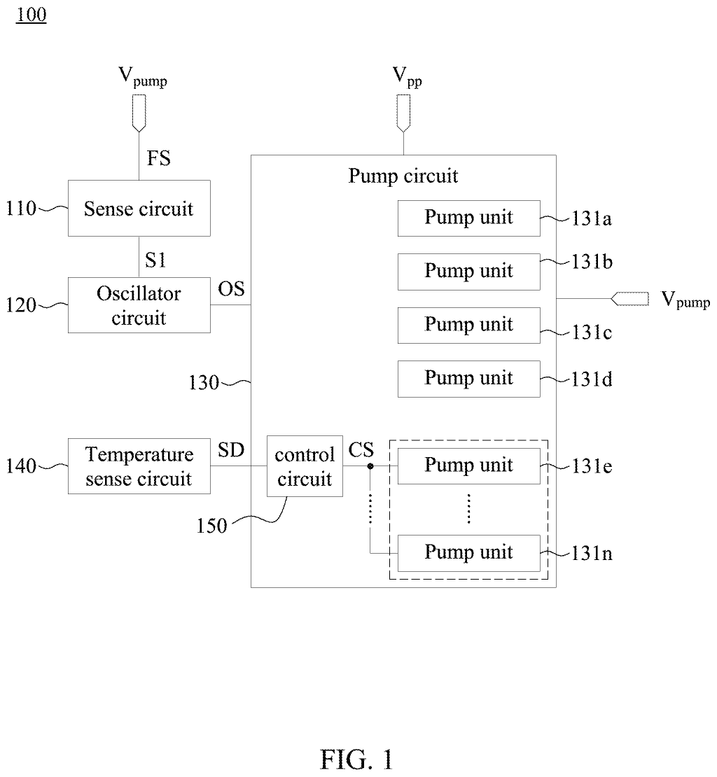

Please refer to FIG. 1. FIG. 1 is a schematic diagram of a voltage supply device 100, in accordance with some embodiments of the present disclosure. The voltage supply device includes a sense circuit 110, an oscillator circuit 120, a pump circuit 130, a temperature sense circuit 140 and a control circuit 150. It should be noted that, in some embodiments, the temperature sense circuit 140 can include the control circuit 150. However, in another embodiment, the control circuit 150 can be included in the pump circuit 130 or be individually included in the voltage supply device 100, but the present disclosure is not limited thereto. The sense circuit 110 is coupled to the oscillator circuit 120. The oscillator circuit 120 is coupled to the pump circuit 130. The temperature sense circuit 140 is coupled to the control circuit 150. The control circuit 150 is coupled to the pump circuit 130.

The sense circuit 110 is configured to receive a feedback signal FS with a pump voltage Vpump generated from the pump circuit 130 and output a signal S1 with a logic value, for example, logic 0 or logic 1. The oscillator circuit 120 is configured to receive the signal S1 and accordingly output an oscillating signal OS when the signal S1 is enabled and has a logic value 1. The pump circuit 130 includes a plurality of pump units 131a-131n. In some embodiments, the pump circuit 130 can be referred as a voltage generating circuit including a plurality of cores to output a voltage. The plurality of cores can be implemented with the plurality of pump units illustrated in the pump circuit 130. Pump units of the plurality of pump units 131a-131n are coupled with each other in parallel, and configured to generate the pump voltage Vpump in response to the oscillating signal OS. In some embodiments, the plurality of pump units 131a-131n can be separated into a pump array 131a-131d and a pump array 131e-131n (circled with dash line in FIG. 1). The temperature sense circuit 140 is configured to sense a system temperature Ts and generate sense data SD, according to the system temperature Ts, for generating a control signal CS which is configured to enable the pump array 131e-131n in the plurality of pump units 131a-131n. Afterward, the control circuit 150 is configured to generate, based on the sense data SD, the control signal CS for enabling or disabling at least one pump units of the pump array 131e-131n. It should be noted that the configuration of the plurality of pump units 131a-131n is determined by the design and requirement of the voltage supply device 100, that is, the amount of pump units being enabled by the control signal CS and the amount of remain pump units in the pump circuit 130 are not limited by the embodiments given in the present disclosure.

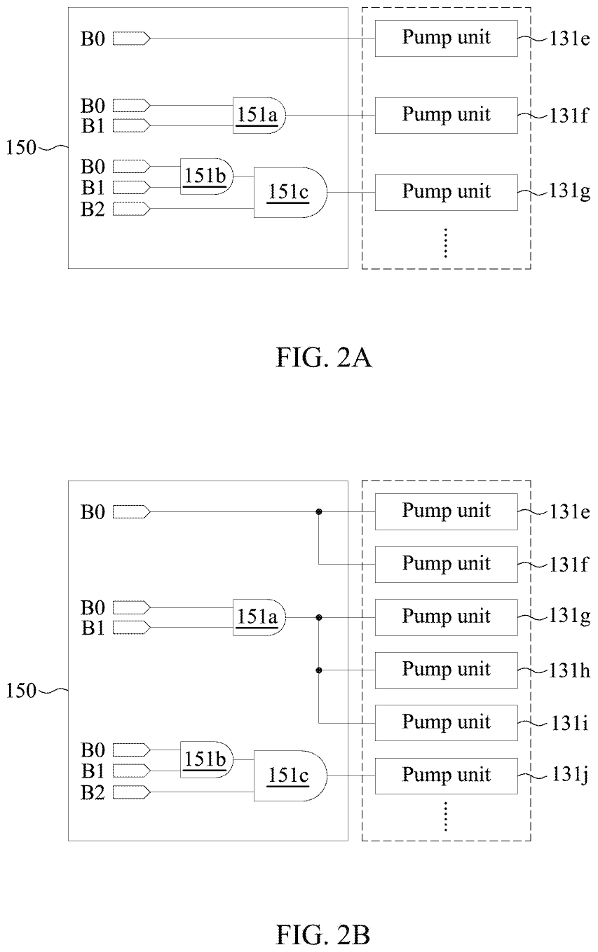

Reference is made with FIG. 2A and FIG. 2B. FIG. 2A and FIG. 2B are schematic diagrams illustrating the control circuit 150 and the pump array 131e-131n, in accordance with some embodiments as shown in FIG. 1 of the present disclosure. As the embodiments shown in FIG. 2A and FIG. 2B, the control circuit 150 including a plurality of logic gates coupled to corresponding pump units of the pump array 131e-131n is coupled to the pump array 131e-131n. The plurality of logic gates 151a-151c in some embodiments can be a plurality of AND gates. The plurality of logic gate 151a-151c are connected between a plurality of input terminal B0-B2 of the plurality of logic gate 151a-151c configured to receive the control signal CS and the pump array 131e-131n. For example, in some embodiments shown in FIG. 2A, the input terminal B0 is coupled to the pump unit 131e, the input terminals B0, B1 are coupled to the pump unit 131f through the logic gate 151a. The input terminals B0, B1 are coupled to the logic gate 151b, an output terminal of the logic gate 151b and the input terminal B2 coupled to the logic gate 151c, and an output terminal of the logic gate 151c is coupled to the pump unit 131g-131n. Furthermore, in some other embodiments as shown in FIG. 2B, the input terminals B0-B2 and the logic gates 151a-151c can be coupled to more than one pump unit. For illustration, the input terminal B0 is coupled to the pump units 131e and 131f. The input terminals B0, B1 are coupled to the logic gate 151a, and the output terminal of the logic gate 151a is coupled to the pump units 131g-131i. The output terminal of the logic gate 151b coupled with the input terminals B0-B2 is coupled with the logic gate 151c, and the output terminal of the logic gate 151c is coupled to the pump units 131j-131n. For ease of understanding, the input terminals B0-B2 connected to the corresponding the pump units are illustrated separately. The number of input terminals and logic gates are given for an exemplary purpose. Other configurations, the number of input terminals and logic gates or the types of logic gates are within the scope of the present disclosure.

In some other embodiments, each of a plurality of logic gates can be connected each one of pump units. Furthermore, the plurality of logic gates cannot be included in the control circuit 150, but can be included in the pump circuit 130 in order to receive the signal generated by the control circuit 130 to enable or disable the corresponding pump units connected with the plurality of logic gates. In such a way that all the pump units included in the pump circuit 130 are controlled by the control signal CS to be enabled.

As the embodiments aforementioned, for example, the control circuit 150 receives the sense data SD corresponding to a certain system temperature and generates the control signal with 3-bit value such as value 001. That is, the first bit is 1 allocated at the most right. The second bit is 0 allocated in the middle of the value. The third bit is 0 allocated at the lost left. In some embodiments as shown in FIG. 2A, after receiving the control signal CS with a value 001, the input terminal B0 in response to the first bit of the value, which is 1, outputs a signal to enable the pump unit 131e. Furthermore, the logic gate 151a operating as an AND gate, and outputs a signal with value 0 which do not enable the pump unit 131f. Similarly, the logic gate 151b operating as an AND gate receives the first bit (the value is 1) and the second bit (the value 0) via the input terminal B0 and B1 respectively, and outputs a signal with value 0 to the logic gate 151. The logic gate 151c operating as an AND gate receives the signal with value 0 from the logic gate 151 and the signal with value 0 as the third bit from the input terminal B2, and as a result, outputs a signal with value 0 which disabled the pump units 131g-131n. Hence, in the embodiment shown in FIG. 2A, among the pump array 131e-131n, only the pump unit 131e is enabled when the control signal CS with the value 001. Likewise, in the embodiment shown in FIG. 2B, when the control signal CS with the value 001, only the pump unit 131e, 131f in the pump array 131e-131n are enabled. The detail of the operation of the control circuit 150 and the pump array 131e-131n will be discussed in the following paragraphs. The control signal CS with 3-bit value is given for an exemplary purpose, but the present disclosure is not limited therein.

For illustration, in some embodiments of the voltage supply device 100, the sense circuit 110 in FIG. 1 includes a comparator configured to compare the pump voltage Vpump of the feedback signal FS with a reference voltage in the voltage supply device 100. When a difference between the pump voltage Vpump and the reference voltage is larger than a threshold value, the sense circuit enables the signal S1 to have a logic 1 and outputs to the oscillator circuit 120 in order to increase the pump voltage Vpump through the pump circuit 130. On the other hand, the oscillator 120 is disabled when the signal S1 received from the sense circuit 110 having logic 0. The oscillator 120 outputs the oscillating signal OS when the signal S1 has a logic value 1. The oscillating signal OS can be any electrical signal with a fixed oscillating frequency and magnitude, such as a clock signal. And then, in response to the oscillating signal OS, the pump array 131a-131d output the pump voltage Vpump.

In some embodiments, the voltage supply device 100 illustrated above operates as a power system to provide memory arrays in a DRAM circuit an operation voltage and operation current. It is known for a person having ordinary skill in the art that as the system temperature of the DRAM circuit increases, the required operation current of the memory arrays increases. Alternately, the voltage supply device 100 requires providing greater current to the memory arrays. For example, when the required operation current corresponding the system temperature at 85° C. is 50 milliampere (mA), ten pump units are needed to provide sufficient current while each pump unit provides current with 5 mA. As system temperature increases to 100° C. and the required operation current turns to be 55 mA, apart from the original ten pump unit, one spare pump unit configured in the voltage supply device 100 is enabled to provide compensated current for the increase of the system temperature. If the system temperature is continuously increasing during the operation, more spare pump units are enabled to provide sufficient compensated current. In other words, the spare pump units can be enabled or disabled according to the system temperature in order to manage power consumption caused by the spare pump units.

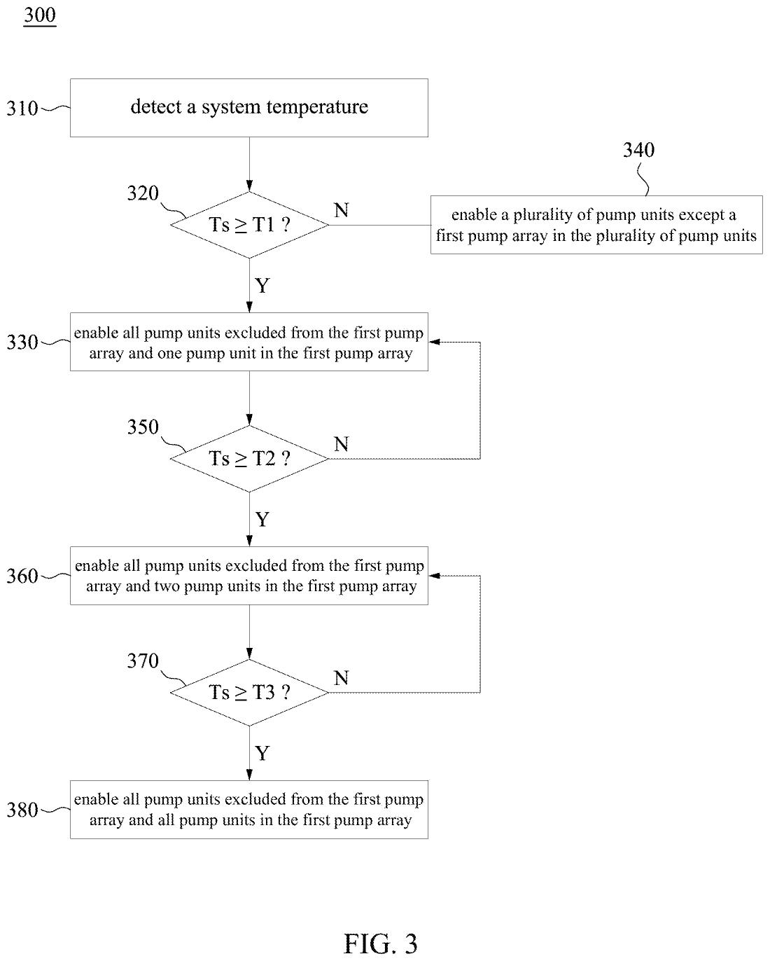

Reference is made to FIG. 3. FIG. 3 is a flow chart of a method 300 illustrating operations of the voltage supply device 100 in FIG. 1, in accordance with some embodiments of the present disclosure. Please refer to FIG. 1, FIG. 2A and FIG. 3 together. In the step 310, the temperature sense circuit 140 detects or senses a system temperature Ts during the operation of the DRAM circuit and generates the sense data SD with the information of the system temperature Ts. In some embodiments, after detecting the system temperature Ts, the control circuit 150 receives the sense data SD indicating that, for example, the system temperature is 84° C.

Next, by performing the step 320, in some embodiments, the control circuit 150 is configured to determine whether the system temperature Ts is above a first temperature T1 (i.e., 85° C., the system temperature of ordinary DRAM circuit operating under normal condition, provided by JTAG template) based on the sense data SD and accordingly output the control signal CS and control, by the control signal CS, a number of pump units 131a-131n in the pump circuit 130 that is configured to generate the pump voltage Vpump, to be enabled. When the system temperature Ts is above the first temperature T1, the step 330 is performed. Otherwise, the step 340 is performed.

In step 340, in some embodiments, when the system temperature is below the first temperature T1, the control circuit 150 is configured to disable the pump array 131e-131n with the control signal CS having value 000 while the pump array 131a-131d is enabled to output the pump voltage Vpump by receiving the oscillating signal OS generated by the oscillator circuit 120. To put in another way, the pump array 131e-131n is electrically disconnected to the oscillator circuit 120.

On the other hand, in step 330, in some embodiments, the pump array 131a-131d is enabled and the control circuit 150 is further configured to enable at least one pump unit of the pump array 131e-131n with the control signal CS having a value 001. As the embodiment shown in FIG. 2A, by receiving the control signal CS passed through the input terminal B0, the pump unit 131e of the pump array 131e-131n is enabled and the remaining pump units in pump array 131e-131n are still disabled. In other words, the control circuit 150 is further configured to conduct the pump unit 131e of the pump array 131e-131n to the oscillator circuit 120 for receiving the oscillating signal OS. Similarly, in the embodiment shown in FIG. 2B, the pump units 131e, 131f are enabled.

Next, in the step 350, in some embodiments, the control circuit 150 continues to determine whether the system temperature Ts is above a second temperature T2, for example, 100° C. When the system temperature Ts ranges between the first temperature T1 (i.e., 85° C.) and the second temperature T2 (i.e., 100), the step 330 is performed continuously. When the system temperature Ts is above the second temperature T2, the step 360 is performed.

In the step 360, in some embodiments, the pump array 131a-131d remains enabled and the control circuit 150 is further configured to enable more pump unit of the pump array 131e-131n with the control signal CS having a value 011. As the embodiment shown in FIG. 2A, the control signal CS received by the input terminals B0, B1, through the logic AND gate 151a outputting a signal with logic 1 (enable signal), the pump units 131e and 131f of the pump array 131e-131n are enabled. Similarly, in the embodiment shown in FIG. 2B, the pump units 131e-131i are enabled.

In addition, in the step 370, the control circuit 150 continues to determine whether the system temperature Ts is above a third temperature T3, for example, 131° C. When the system temperature Ts ranges is below the third temperature T3, the step 360 is performed continuously. When the system temperature Ts is above the second temperature T3, the step 380 is performed.

In the step 380, in some embodiments, the pump array 131a-131d remains enabled and the control circuit 150 is further configured to enable all pump units of the pump array 131e-131n with the control signal CS having a value 111.

As discussed above, in some embodiments, the pump units in the pump array 131e-131n are controlled by the control signal SC to be separately enabled. For example, as the embodiment shown in FIG. 2A, when the control signal CS corresponding to the system temperature Ts at 125° C., which is in between the second temperature T2 (i.e., 100° C.) and the third temperature T3 (i.e., 131° C.), has a value 011, only the pump unit 131e and 131f are enabled and the remaining pump unit of the pump array 131e-131n remain disabled.

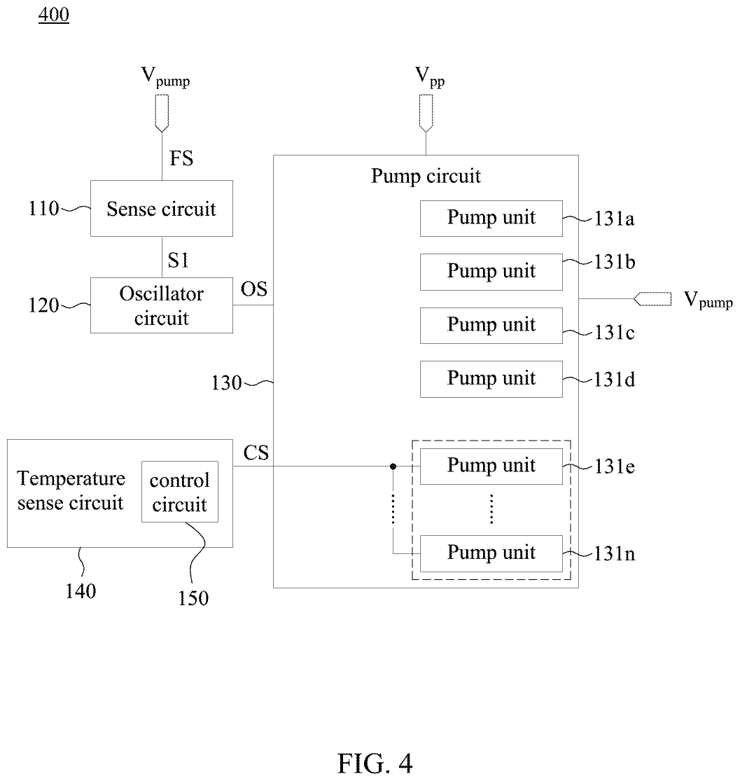

Reference is made as in the FIG. 4. FIG. 4 is a schematic diagram of a voltage supply device 400, in accordance with some embodiments of the present disclosure. With respect to the embodiments of FIG. 4, like elements in FIG. 1, are designated with the same reference numbers for ease of understanding. The specific operations of similar elements, which are already discussed in detail in above paragraphs, are omitted herein for the sake of brevity, unless there is a need to introduce the co-operation relationship with the elements shown in FIG. 1. The difference between FIG. 1 and FIG. 4 is that the temperature sense circuit 140 is configured to include a control circuit 150 to, based on sense data SD generated by the temperature sense circuit 140, generate a control signal for enabling or disabling at least one pump unit of the pump unit array 131e-131d.

Corresponding to the method 300, in some embodiments, when the system temperature Ts increases, the temperature sense circuit 140 is further configured to generate updated sense data SD for modifying the control signal CS in order to enable an increased number of pump units in the pump array, for example, the pump array 131e-131n is FIG. 2A. Specifically, in some embodiments, when the system temperature Ts increases from 82° C. to 88° C. during the operation, signifying that the memory array (not shown in the figures) needs greater current compared to the required current at lower temperature, the temperature sense circuit 140 generates updated sense date SD with the information of the system temperature Ts indicating 88° C. Moreover, the control circuit 150 included in the temperature sense circuit 140, not included in the temperature sense circuit 140 or included in the pump circuit 130 modifies the control signal CS, so that the control CS is updated from having value 000 to value 001. Consequently, as shown in FIG. 2A, one more pump unit, like the pump unit 131e, is enabled.

By the same token, in some embodiments, when the system temperature Ts decreases from 135° C. to 105° C. during the operation, signifying that the memory array (not shown in the figures) needs less current compared to the required current at higher temperature, the temperature sense circuit 140 generates updated sense date SD with the information of the system temperature Ts indicating 105° C. Moreover, the control circuit 150 included in the temperature sense circuit 140, not included in the temperature sense circuit 140 or included in the pump circuit 130 modifies the control signal CS, so that the control CS is updated from having value 111 to value 011. Consequently, as shown in FIG. 2A, the number of pump units, being enabled, in response to the system temperature decreases. That is, the pump units 131g-131n are controlled to be disabled in response to the control circuit 150.

It should be noted that, as the embodiments aforementioned, the control circuit 150 can be configured to modify the control signal CS regarding different temperature intervals. In some embodiments, the control signal CS can be modified during every 5° C. or non-linear temperature interval, such like 85° C.-95° C., 96° C.-111° C. and 112° C.-132° C. Specifically, for example, the temperature interval can be 81° C.-85° C., 86° C.-90° C., 91° C.-95° C., 96° C.-100° C. and 101° C.-105° C., etc. In this way, when the system temperature Ts increases from 81° C. to 100° C., the control signal CS can be modified for four times, accordingly, and the number of pump units being enabled in the pump array 131e-131n varies four times, for example, from zero pump unit enabled to three pump units enabled. In other embodiments, the control circuit 150 can be configured to generate the control signal CS based on the sense signal SD and a threshold temperature. When the system temperature Ts is below or equal to the threshold temperature, no spare pump units, for example pump units 131e-131n, are enabled. When the system temperature Ts is above the threshold temperature, all the spare pump units are enabled. The number of pump units in the pump array 131e-131n, the temperature intervals are given for an exemplary purpose of ease of understanding the present disclosed, but the present disclosure is not limited therein.

Furthermore, the pump units in the present disclosure can be identical to each other, providing same current value, or different to each other. Various ways to implement the function of the pump units in the pump circuit are within the contemplated scope of the present disclosure.

In summary, in various embodiments of the present disclosure, by enabling or disabling the a plurality of pump unit configured to provide the voltage according the a control signal corresponding to the system temperature of the DRAM circuit, the power consumption of the DRAM circuit during operation at high and low temperature can be managed preciously without complicated configuration of circuits.

It is noted that, the drawings, the embodiments, and the features and circuits in the various embodiments may be combined with each other as long as no contradiction appears. The circuits illustrated in the drawings are merely examples and simplified for the simplicity and the ease of understanding, but not meant to limit the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a plurality of pump units configured to generate a pump voltage in response to an oscillating signal, wherein the pump voltage generates an operation current for a memory circuit;
a temperature sense circuit configured to sense a system temperature of the memory circuit and to generate sense data according to the system temperature of the memory circuit; and
a control circuit coupled to a first pump array in the plurality of pump units, and configured to generate a control signal according to the sense data for enabling or disabling at least one pump unit of the first pump array to change the pump voltage generated by the plurality of pump units so as to change the operation current of the memory circuit.

2. (canceled)

3. The device of claim 1, wherein the control circuit comprises a plurality of logic gates coupled to corresponding pump units of the first pump array.

4. The device of claim 3, wherein the plurality of logic gates are a plurality of AND gates.

5. The device of claim 3, wherein
when the system temperature is below a first temperature, the control circuit is further configured to disable the first pump array,
when the system temperature ranges between the first temperature and a second temperature, the control circuit is further configured to enable at least one pump unit of the first pump array, and
when the system temperature is above the second temperature, the control circuit is further configured to enable all pump units of the first pump array.

6. The device of claim 3, wherein when the system temperature ranges between a first temperature and a second temperature, the control circuit is further configured to enable at least one pump unit of the first pump array.

7. The device of claim 1, wherein
when the system temperature increases, the temperature sense circuit is further configured to generate updated sense data for modifying the control signal in order to enable an increased number of pump units in the first pump array.

8. (canceled)

9. The device of claim 1, wherein pump units in the first pump array are controlled by the control signal to be separately enabled.

10. The device of claim 1, wherein the plurality of pump units are coupled to a plurality of logic gates, and controlled by the control signal to be enabled.

11. A device, comprising:
a sense circuit configured to receive a feedback signal and output a first control signal;
an oscillator circuit coupled to the sense circuit, and configured to receive the first control signal and accordingly output an oscillating signal when the first control signal is enabled;
a voltage generating circuit comprising a plurality of first cores and a plurality of second cores, wherein the plurality of first cores and the plurality of second cores are configured to output a voltage in response to the oscillating signal, and the voltage generates an operation current for a memory circuit;
a temperature sense circuit coupled to the voltage generating circuit, and configured to provide sense data for generating the second control signal according to a system temperature of the memory circuit detected by the temperature sense circuit; and
a control circuit connected to the plurality of second cores, and configured to generate a second control signal based on the sense data for enabling or disabling at least one second core of the plurality of second cores to change the voltage generated by the voltage generating circuit so as to change the operation current of the memory circuit.

12. (canceled)

13. The device of claim 11, wherein the control circuit is further configured to conduct at least one second core of the plurality of second cores to the oscillator circuit for receiving the oscillating signal.

14. The device of claim 11, wherein when the system temperature is below a first temperature, the plurality of first cores output the voltage while the plurality of second cores are disabled.

15.-16. (canceled)

17. A method, comprising:
sensing, by a temperature sense circuit, a system temperature of a memory circuit, to generate sense data;
generating a control signal corresponding to the sense data; and
controlling, by the control signal, a number of pump units in a pump circuit that is configured to generate a pump voltage, wherein the pump voltage generates an operation current for the memory circuit.

18. The method of claim 17, further comprising:
determining whether the system temperature is above a first temperature,
when the system temperature is above the first temperature, enabling at least one pump unit in the pump circuit by the control signal.

19. The method of claim 18, further comprising:
receiving an oscillating signal generated by an oscillator circuit to generate the pump voltage,
wherein when the system temperature is below the first temperature, electrically disconnecting the oscillator circuit and the pump units.

20. The method of claim 17, wherein controlling the number of pump units comprising:
by modifying the control signal, increasing the number of pump units, being enabled, in response to the system temperature increasing; and
decreasing the number of pump units, being enabled, in response to the system temperature decreasing.
